(19) United States
(12) Patent Application Publication
(10) Pub. No.: US 2011/0188226 A1
(43) Pub. Date: Aug. 4, 2011

(54) SHIELD APPARATUS FOR EMI SHIELDING

(75) Inventor: Sun-Ki KIM, Kyeonggi-do (KR)

(73) Assignee: JOINSET CO., LTD., Kyeonggi-do (KR)

(21) Appl. No.: 12/957,762

(22) Filed: Dec. 1, 2010

(30) Foreign Application Priority Data
Feb. 4, 2010 (KR) 10-2010-0010470
Sep. 20, 2010 (KR) 10-2010-0092606

(51) Int. Cl. H05K 9/00

(52) U.S. Cl. 361/818

(57) ABSTRACT

A shield apparatus for EMI (ElectroMagnetic Interference) shielding is provided. The shield apparatus includes a case and a metal clip. The case is box-shaped with at least one open side, and has a recess defined from the open side into a sidewall. The metal clip is housed in the recess, and is resiliently inserted on the sidewall to retain a certain height.

### FIELD OF THE INVENTION

The present invention relates to a shield apparatus for EMI (ElectroMagnetic Interference) shielding—particularly, to a shield apparatus for EMI shielding that can be reflow-soldered with solder cream after it is surface-mounted with a vacuum pickup on solder cream formed on a PCB (Printed Circuit Board) ground pattern—and more particularly, to a shield apparatus for EMI shielding that can be reliably connected electrically to a PCB ground pattern, for good EMI shielding effectiveness and soldering strength and for easy mounting and separating.

### DESCRIPTION OF THE RELATED ART

As modern electronic devices and communication devices use higher frequencies and become more miniaturized and highly integrated, they are greatly affected by heat, static electricity, and EMI. For example, as high frequency electronic components such as microprocessors and memories are given faster processing speeds, greater storage capacities, and smaller dimensions, they generate greater amounts of heat and EMI. Such high frequency electronic components and modules are also greatly affected by heat, static electricity, and EMI from the surrounding environment.

Thus, in order to prevent EMI generated by such high frequency electronic components and modules from being transmitted externally, and in order to also protect such high frequency components and modules from externally-generated EMI, such high frequency components and modules are covered with a shield case for EMI shielding, after which the bottom surface of the shield case is electrically and mechanically connected to the PCB ground pattern, to shield the high frequency components and modules from EMI.

Here, the shield case for EMI shielding is formed of an electrically conductive material such as a metal sheet for EMI shielding, and is box-shaped with at least one open side to cover electronic components and modules mounted on a PCB.

A shield case for EMI shielding must electrically contact a ground pattern of a PCB in a reliable manner to shield electronic components or modules within from EMI. A shield case for EMI shielding should also be strong enough to withstand and protect electronic components or modules within from a certain level of external force and shock. Thus, a shield case for EMI shielding is formed in a plate shape of a metal material that has high mechanical strength and low cost, and for some applications, holes may be defined in the top surface of the shield case for EMI shielding to dissipate heat. Especially in the cases of high frequency electronic devices such as mobile phones that are small and carried on person, a shield case for EMI shielding that is both thin and strong is required.

Preferably, a shield case for EMI shielding should be separable from a PCB ground pattern to facilitate repair of electronic components or modules within.

Also, an EMI isolation wall may be formed on the reverse surface of the shield case for EMI shielding to electrically separate high frequency electronic components and modules from one another, and respectively separate the high frequency electronic components and modules and shield EMI.

A shield case for EMI shielding is thus mounted on a ground pattern of a PCB.

In the related art, a solderable metal sheet such as one of stainless steel that is plated with tin, etc. is continually pressed and bent with a press to form shield case for EMI shielding, after which the perimeter on the bottom of the shield case is positioned on a ground pattern of a PCB and soldered for mounting on the ground pattern, or the shield case is inserted and mounted on metal clips that have been pre-soldered on the ground pattern.

Other configurations of shield cases for EMI shielding are products of injection molded plastic that are metal plated, and die cast products of metal such as magnesium. These shield cases are inserted and mounted on metal clips formed on ground patterns of PCBs, or are mounted by soldering.

According to such related art technologies, in order to mount a shield case for EMI shielding on a ground pattern of a PCB, 1) a shield case is either inserted in metal clips pre-soldered on a ground pattern, 2) a shield case is soldered manually on a ground pattern, or 3) a shield case is reflow soldered with solder cream on a ground pattern.

In the above cases, when a shield case is inserted in metal clips pre-soldered on a ground pattern, the following limitations can arise.

1) Pre-mounting a plurality of metal clips on a ground pattern in order to insert a shield case for EMI shielding in the metal clips pre-soldered on the ground pattern is costly.

It is also difficult to perform automated insertion of the shield case for EMI shielding in the metal clips.

To cite a specific example, using a vacuum pickup to surface mount metal clips on solder cream applied to a ground pattern, performing reflow soldering, and then inserting and mounting a shield case on the metal clips involves the following limitations.

a) Reel-packaging the metal clips, which are comparatively complex in structure and lightweight, on carrier tape is a high-cost process.

b) In order to vacuum pickup a metal clip, at least one surface of the metal clip must be flat and preferably, laterally symmetrical, and thus, there are limitations in miniaturizing the dimensions of the metal clip. For this reason, related art metal clips are made to be considerably greater in length than in width, which drives manufacturing costs up and is highly restrictive in terms of usability.

c) Because a metal clip has a comparatively greater length than width and is lightweight, causing it to wobble during reflow soldering, reliable quality is difficult to achieve. That is, if even one metal clip from among many is slightly offset, attempting to insert a shield case above it can lead to difficulties.

d) Good quality is difficult to provide when inserting a shield case over the metal clips. Specifically, the metal clips and the bottom surface of the shield case must be reliably attached electrically to the ground pattern for good EMI shielding, but if the metal shield case in not sufficiently inserted, EMI shielding effectiveness is reduced.

Also, due to the quantity of solder cream provided on a ground pattern, after reflow soldering, the bottom surface of a shield case is difficult to reliably contact electrically and mechanically with the bottom surface of a metal clip using solder cream, so that EMI shielding effectiveness and soldering strength are poor.

e) Given that metal shield cases are structurally diverse, inserting and mounting one simultaneously in a number of metal clips that are mounted on a ground pattern is difficult.

f) Lowering costs through mass-production is problematic, given the difficulty in properly controlling insertion and removal forces between shield cases and metal clips of diverse configurations.

2) With the second limitation above, when a shield case for EMI shielding is soldered manually and mounted on a ground pattern, uniform quality is difficult to ensure, and the cost for soldering is high.

Also, after a shield case is soldered to a ground pattern, it is difficult to separate the shield case from the ground pattern, rendering re-work difficult.

3) With the third limitation above, when a shield case for EMI shielding is positioned with a vacuum pickup on solder cream on a ground pattern and mounted by reflow soldering, it is difficult to separate the shield case from the ground pattern after being soldered.

Also, the perimeter on the bottom of the soldered shield case for EMI shielding is relatively thin, causing soldering strength to be weak and much movement during reflow soldering.

Further, when material that is difficult to solder is used for the shield case, a solderable metal must first be plated on the surface of the shield case in order to perform soldering. For example, if stainless steel with comparatively high mechanical strength and low cost is used, soldering is made difficult, so that tin or other easily solderable metal must be plated.

Because there are many kinds of metal shield cases in the related art, a large number of companies have been manufacturing metal shield cases on a by-order basis, while metal clips are also manufactured by many companies, including Autosplice Inc., USA (www.autosplice.com), Kitagawa Industry Co., Ltd., Japan (www.kitagawaind.com) and Pocons Co., Ltd., Korea (www.pocons.co.kr).

### SUMMARY OF THE INVENTION

To substantially overcome one or more problems due to the limitations and disadvantages of the related art, it is an object of the present invention to provide a shield apparatus for EMI shielding capable of being surface mounted with a vacuum pickup and reflow soldered.

Another object of the present invention is to provide a shield apparatus for EMI shielding with high EMI shielding effectiveness and soldering strength.

A further object of the present invention is to provide a shield apparatus for EMI shielding that can easily be applied to diversely configured ground patterns, and particularly, to a narrow ground pattern.

An even further object of the present invention is to provide a shield apparatus for EMI shielding that enables easy automation and re-working and has a low manufacturing cost.

A still further object of the present invention is to provide a shield apparatus for EMI shielding whose surface mounting produces good yield.

A yet further object of the present invention is to provide a shield apparatus for EMI shielding with improved thermal conductivity and electric wave absorbency, or capable of EMI isolation.

An additional object of the present invention is to provide a shield apparatus for EMI shielding with reliable levels of insertion and removal force.

According to an aspect of the present invention, there is provided a shield apparatus for EMI shielding, including: a case of metal that is electrically conductive and box-shaped with at least one open side, and having a recess defined from an end of a sidewall thereof defining the open side; and a metal clip having a bottom surface that is wider than a thickness of the sidewall of the case, the metal clip housed in the recess, resiliently inserted on the sidewall, and electrically connected to the case, wherein at least the bottom surface of the metal clip does not project from within the recess, and the shield apparatus is lifted with a vacuum pickup and supplied on a ground pattern of a PCB (Printed Circuit Board) and soldered at the bottom surface of the metal clip.

The case may be manufactured by pressing a high-strength metal sheet that is difficult to reflow solder with solder cream.

The metal clip may be formed with one of tin and silver plated on a high-strength metal sheet that is difficult to reflow solder with solder cream.

The sidewall may define a notch respectively in an outer surface and an inner surface thereof at regions proximate to a bottom surface of the recess, or the sidewall may define a through-hole therethrough, and resiliently opposed portions of the metal clip may be seated in each of the notches, respectively, or in the through-hole.

The case may define a plurality of heat dissipating holes in a top surface thereof.

The shield apparatus may further include one selected from an EMI absorbing rubber sheet, a heat conductive rubber sheet, and an EMI shielding electrically conductive rubber isolating wall, formed on an opposite surface of a top surface of the case.

The metal clip may be formed as a single piece including at least one pair of supporting portions extending vertically from either end widthwise of the bottom surface of the metal clip, and a pair of resilient contacting portions bent to extend at a predetermined angle inward from each of the supporting portions, respectively.

The bottom surface of the metal clip may define a plurality of holes, and solder balls may be mounted on a portion of the plurality of holes.

The metal clip may have the same dimensions and material when provided in plurality, and the dimensions of the recesses may be the same.

A side opposite the open side may be additionally open, and an electrically conductive cover covering the additionally open side may be further included.

The electrically conductive cover may have a sheet configuration and cover the additionally open side by being inserted in a slot defined in the sidewall of the case.

The electrically conductive cover may be formed of a base and sidewalls integrally extending perpendicularly from edges of the base, and cover the additionally open side by being mechanically inserted over a top surface of the case.

The electrically conductive cover may have a sheet configuration and cover the additionally open side, with an electrically conductive adhesive tape interposed therebetween.

The electrically conductive cover may include a base, and sidewalls integrally extending perpendicularly from any one pair of opposed edges of the base, and the electrically conductive cover may cover the additionally open side by being slid from side surfaces of the case and coupled to the case.

The electrically conductive cover may include a rib respectively projecting along inner sides of the sidewalls thereof, the case may define a slot respectively along the sidewalls thereof, and the rib formed respectively on the sidewalls of the electrically conductive cover may be fitted in the slot defined respectively in the sidewalls of the case to slide therealong, to couple the electrically conductive cover to the case.

Opposed edges of the additionally open side may be connected to each other by connecting portions respectively having a land formed at a center thereof for a vacuum pickup.

The shield apparatus may be reel-packaged on carrier tape or is packaged on a tray for surface mounting.

At least a portion of the top surface of the case may be a flat surface for a vacuum pickup.

The shield apparatus may be surface mounted with a vacuum pickup and reflow soldered with solder cream.

An insertion force and a removal force of the metal clip with respect to the case may be 100 gf or greater.

After the shield apparatus is soldered to the ground pattern of the PCB, the case may be separated from the metal clip by means of a predetermined removal force.

The bottom surface of the metal clip may retain a horizontal disposition.

According to another aspect of the present invention, there is provided a PCB (Printed Circuit Board) on which the above shield apparatus is surface mounted and soldered.

### BRIEF DESCRIPTION OF THE DRAWINGS

The above objects and other advantages of the present invention will become more apparent by describing in detail preferred embodiments thereof with reference to the attached drawings in which:

FIG. 1 is a view illustrating a reflow solderable shield apparatus for EMI shielding according to an embodiment;

FIG. 2 is a view illustrating a metal clip applied to a shield apparatus according to another embodiment;

FIG. 3 is a view illustrating the process of inserting a metal clip on a case of a shield apparatus according to another embodiment;

FIG. 4 is a view illustrating a shield apparatus according to another embodiment;

FIG. 5 is a view illustrating a shield apparatus according to another embodiment; and

FIG. 6 is a view illustrating shield apparatuses according to other embodiments.

### DETAILED DESCRIPTION OF THE PREFERRED EMBODIMENT

Now, preferred embodiments of the present invention will be described in detail with reference to the accompanying drawings.

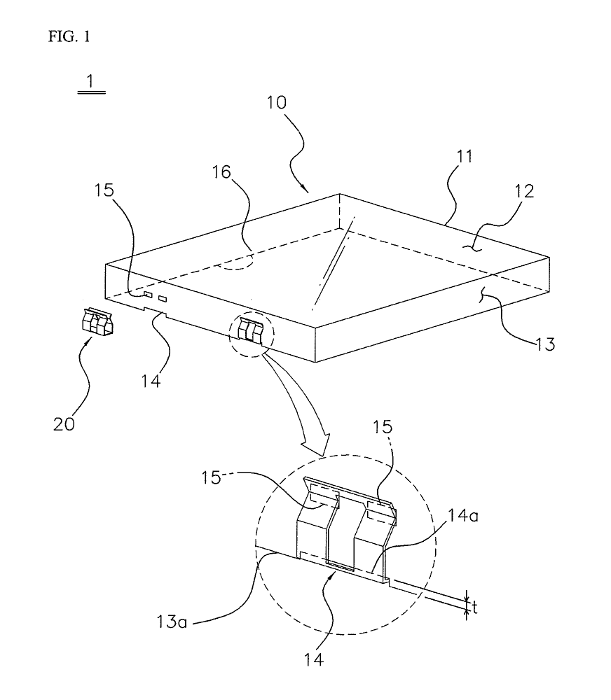

FIG. 1 is a view illustrating a shield apparatus 1 for EMI shielding according to an embodiment.

A shield apparatus 1 for EMI shielding according to a first embodiment includes an electrically conductive case 10 of a box-shape with one open side and a recess 14 formed from an edge of an opening 16 defining the open side to a sidewall 13, and a metal clip 20 inserted in the recess 14 and fixed on and electrically connected to the case 10, whereby the metal clip 20 is at least fixed so as not to project from an end 13a of the sidewall 13 of the case 10.

The bottom surface of the metal clip 20 may be horizontally disposed.

The top surface of the recess 14 may be horizontally disposed.

According to this configuration, the bottom surface of the metal clip 20 is electrically contacted to solder cream formed on a ground pattern of a PCB by means of soldering, and the end 13a of the sidewall 13 of the case mechanically coupled to the metal clip 20 mounted on the PCB ground pattern is electrically contacted to the PCB ground pattern, so that the shield apparatus 1 is overall electrically contacted to the PCB ground pattern in a reliable manner and performs EMI shielding for the electronic components or modules within the shield apparatus 1.

If the case 10 with the metal clip 20 mounted thereon is positioned atop the PCB with, say, a vacuum pickup, the end 13a of the sidewall 13 of the case 10 contacts the PCB, and the metal clip 20 fixed so as not to project from the end 13a of the sidewall 13 of the case 10 is electrically contacted to the solder of the PCB.

While the case 10 may have a simple rectangular box shape with flat surfaces, it may be formed in a more complex shape according to the structure of a ground pattern. In the latter case, a gripping mark may be formed on the case 10 to indicate what part of the case 10 a technician should grip in order to easily perform re-working. Specifically, when the case 10 is separated through re-working after the metal clip 20 of the shield apparatus 1 is soldered to the ground pattern of the PCB, the case 10 may be easily separated from the metal clip 20 by gripping the gripping mark and pulling.

The material used for the case 10 of the shield apparatus 1 may be stainless steel that is thin—with a thickness from about 0.07 mm to about 0.30 mm, has good mechanical strength, and is inexpensive. Here, while stainless steel is not easily solderable, this does not present a problem, as the case 10 itself does not have to be soldered. The case 10 is not limited to stainless steel, however, and may use a material selected from metals such as magnesium that is die cast to form a metal structure, and a heat resistant polymer resin having metal plated on its surface. In this case, the dimensions of the case 10 are unavoidably enlarged.

A top surface 12 of the case 10 is formed to have at least one flat portion, and the flat portion enables surface mounting with a vacuum pickup. A plurality of heat dissipating holes may be defined in the top surface 12 of the case 10 to dissipate internal heat.

An EMI absorbing rubber sheet, heat conducting rubber sheet, or electrically conductive rubber gasket may be formed on the reverse surface of the top surface 12 of the case 10, in order to transfer heat or EMI generated from the electronic components and modules installed within the shield apparatus 1 or protect the electronic components and modules from heat or EMI.

An isolating wall of an electrically conductive silicon rubber may be formed on the opposite surface to the top surface 12 of the case 10, to isolate electrical components and modules within the shield apparatus 1 from one another and shield EMI, and in this case, mechanical strength of the case 10 is improved by the electrically conductive isolating wall.

The isolating wall, however, is not limited thereto, and may be a metal member integrally formed with the case 10 or a metal plate welded to the case 10.

As described above, a recess 14 is formed from the end 13a of the sidewall 13, to correspond in length and height to the metal clip 20, so that when the metal clip 20 is inserted into the recess 14, the recess 14 is almost filled by the metal clip 20. While there are 2 recesses 14 shown formed in one side of a sidewall in the present embodiment, the positions and numbers of recesses 14 are not limited hereto.

The dimensions and shapes of the recesses 14 may all be the same.

The height of the recess 14 may be of a measurement that prevents the metal clip 20 from being exposed to the outside of the end 13a of the sidewall 13 of the case 10 when completely inserted in the recess 14.

At least one recess 14 may be defined in a laterally symmetrical manner, respectively, in two or more sidewall 13 directions, in order to improve workability during reflow soldering of the shield apparatus 1 and provide good soldering strength after reflow soldering.

Selectively, a pair of notches 15 may be defined in the sidewall 13 at a distance upward from the recess 14, and resilient contacting portions 24 and 25 (described below) of the metal clip 20 may be inserted in the notches 15. Through this configuration, when the metal clip 20 is inserted in the recess 14 of the case 10, horizontal and vertical displacement can be entirely prevented, and particularly, even if the metal clip 20 does not contact the bottom surface of the recess, it can retain a horizontal disposition and a certain height from the end 13a of the sidewall 13 of the case 10.

In this case, the metal clip 20 is easy to insert in the recess 14.

The notch 15 may be formed as a V-shaped notch or defined as a through-hole through the sidewall 13, and the notch 15 or through-hole may be defined through press forming during the manufacture of the case 10. In contrast to this embodiment, a notch may be defined in the metal clip 20, and a projection may be formed on the sidewall 13 of the case 10 to correspond and couple to the notch.

The material used for the metal clip 20 may be stainless steel that is thin—with a thickness from about 0.07 mm to about 0.25 mm, has good mechanical strength, and is inexpensive. While stainless steel is not easily solderable, this does not present a problem, because difficulties in soldering including reflow soldering can be resolved by plating easily solderable tin or silver. Materials used are not limited hereto, however, and may be a copper alloy such as beryllium copper that is expensive but solderable and has good resilience.

The metal clips 20 may be of the same dimensions and materials.

The width of the metal clip 20 may be about 0.5 mm to about 2.0 mm, the length may be about 3 mm to about 10 mm, and the thickness of the metal clip 20 material may be about 0.07 mm to about 0.25 mm. The width at the bottom surface 21 of the metal clip 20 may be about the same as the width of the ground pattern of the soldered PCB.

At least one portion of the top surface of the metal clip 20 may be configured as a flat surface to allow vacuum pickup of the metal clip 20.

The metal clip 20 may be formed as a single body that may include supporting portions 22 and 23 extending vertically from either widthwise end of the bottom surface 21, and resilient contacting portions 24 and 25 that are bent and extend a certain angle inward from the supporting portions 22 and 23.

Thus, the metal clip 20 forms the resilient contacting portions 24 and 25 to provide insertion force and removal force.

While in this embodiment, the resilient contacting portions 24 and 25 are formed in a V-shape corresponding to the notches 15, they may have various other shapes with respect to the notch 15.

Because the metal clip 20 may be manufactured in various forms suitable for the recess 14, it easy to provide a standardized metal clip 20 having a suitable removal force required to remove the case 10 from the metal clip 20 for re-working after the shield apparatus 1 is soldered on the ground pattern, and a suitable insertion force required to reinsert the case 10 in the metal clip 20.

After the shield apparatus 1 is soldered on the ground pattern of the PCB, the insertion force and removal force between the metal clip 20 and case 10 may be 100 gf or greater.

Because it is easy to thus standardize the recess 14 and the metal clip 20, lowering of manufacturing costs through mass-production is made possible.

Also, a shield apparatus 1 having suitable insertion force and removal force may be provided by applying the standardized metal clip 20 and controlling the positions and numbers of the recesses 14.

Conversely, it is difficult to provide related art metal clips with suitable levels of insertion force and removal force, given that there are various cases and case recesses of diverse configurations.

Also, when there is no recess, the bottom surface of a metal clip projects to the outside of the bottom surface of a case, so that after soldering, the bottom of a case without a metal clip is difficult to electrically contact with a PCB ground pattern.

Further, because a related art metal clip with a narrow width and extensive length is lightweight and thus prone to shifting in position due to airflow when it is lifted with a vacuum pickup in preparation for reflow soldering, it is difficult to solder the metal clip at a precise location on a PCB ground pattern, and therefore, it is difficult to insert a shield apparatus over a plurality of mounted metal clips.

As described above, the bottom surface of the metal clip 20 may be made horizontal to facilitate reflow soldering.

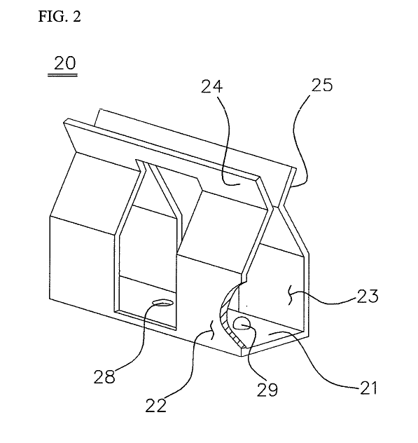

As shown in FIG. 2, a hole 28 may be defined to accommodate solder cream when the quantity of solder cream is large and to provide good soldering strength. Conversely, in order to improve soldering strength or workability, a solder ball 29 may be pre-mounted on the hole 28 to provide reliable reflow soldering.

When the hole 28 is thus defined in the bottom surface of the metal clip 20, residual solder cream is held in the hole 28 when there is a large quantity of solder cream during reflow soldering to give good soldering strength, and the end 13a of the sidewall 13 of the case 10 after soldering is electrically contacted reliably with the ground pattern of the PCB to give effective EMI shielding.

When the quantity of solder cream during reflow soldering is lacking, the solder ball 29 formed on the hole 28 of the metal clip 20 provides solder cream to compensate for the lack thereof, so that the bottom surface of the metal clip 20 is given a strong soldering bond with the ground pattern through the solder cream.

The solder ball 29 may use a material that is similar to solder cream capable of thermal bonding. The solder ball 29 is mounted in the hole 28 using a method selected from mechanical insertion, soldering with solder cream, and a combination thereof. Through reliably contacting the solder cream with the solder ball 29, soldering strength is increased during reflow soldering.

A shield apparatus 1 with the above configuration is completed in its assembly by mechanically inserting the resilient metal clip 20 on the case 10.

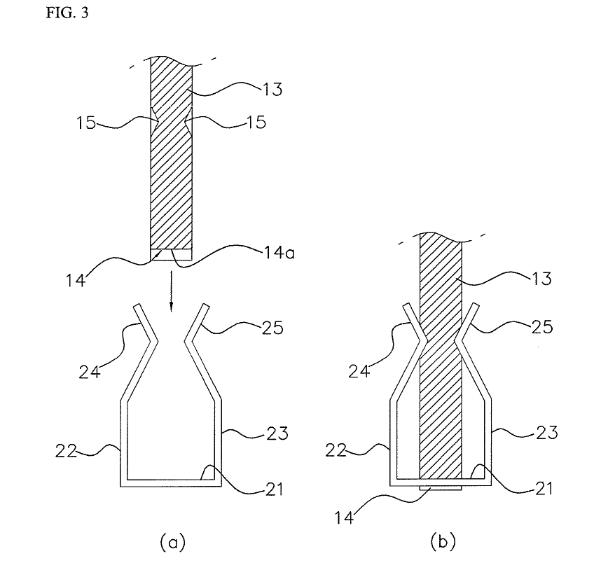

FIG. 3 is a view illustrating the process of inserting a metal clip 20 on a case 10 of a shield apparatus 1 according to another embodiment.

When the metal clip 20 is positioned at the entrance of the recess 14 of the case 10 and is pressed and fitted on the sidewall 13 of the case 10, as the resilient contacting portions 24 and 25 of the metal clip 20 are spread outward to either side and inserted, the bottom surface 21 of the metal clip 20 comes into contact with the bottom surface 14a of the recess 14 and stops. Thus, when the notches 15 are defined in the sidewall 13 of the case 10, the resilient contacting portions 24 and 25 are inserted and stopped.

An automatic insertion machine may be used to insert the metal clip 20 in the recess 14 of the case 10.

The insertion force for inserting the metal clip 20 on the recess 14 may be at least 100 gf and a maximum of 1 kgf, the removal force may be the same, and these forces are provided by the resilient contacting portions 24 and 25 of the metal clip 20.

According to this configuration as shown in FIG. 1, the metal clip 20 is coupled to maintain a state separated by a distance of about ‘t’ from the end portion of the sidewall 13 of the case 10 in the recess 14, and this configuration is the same for all the metal clips 20. Accordingly, when solder cream is applied to the bottom surface of the metal clip 20 for performing reflow soldering, a recess 14 is not formed due to the solder thickness, and it is formed horizontally at about the same level as the end 13a of the sidewall 13 of the recess 14 in which the metal clip 20 is not inserted.

The distance ‘t’ may be determined based on the thickness of solder formed of solder cream and the thickness of the metal clip 20, or may be about 0.02 mm to about 1 mm.

Accordingly, after reflow soldering, the shield apparatus 1 is pressed against the ground pattern of the PCB and solder cream and electrically connected to effectively shield EMI.

Also, after the shield apparatus 1 is soldered, the metal clip 20 may be easily separated from the case 10 by force.

Heat conductive rubber, electrically conductive rubber, or an EMI absorbing body may be additionally formed on the surface opposite the top surface of the case 10.

In this case, the heat transfer performance of the shield apparatus 1 is improved, electrical contact is made easy, or EMI absorption performance is enhanced.

A plurality of shield apparatuses 1 may be reel-taped to enable vacuum picking-up.

If the shield apparatus 1 of the above configuration according to embodiments is supplied to a client through reel taping on a separate carrier tape, surface mounting is made easy for the client who can surface mount the reel-taped shield apparatus 1 on a ground pattern of a PCB by using a surface mounting machine. That is, when a shield apparatus 1 of a certain size and weight or greater is surface mounted with a vacuum pickup and then reflow soldering is performed, due to reduced movement, manufacturing yield is favorable, and automation is made easy. Moreover, when re-working is needed after soldering, the case 10 of the shield apparatus 1 can be separated by force, which facilitates re-working.

Also, there is no need to provide a separate metal clip on the ground pattern of a PCB, as in the related art.

In addition, there is no need to mount a case on a metal clip mounted on the ground pattern of a PCB, as in the related art.

Because a shield apparatus 1 of the present invention does not require a separate metal clip, a product with good yield and reliability can be provided that is suitable for mass production.

From the client's perspective, the following problems may arise when the above-described shield apparatus 1 is reflow soldered to a ground pattern of a printed circuit board.

For example, a vision inspection is performed after electronic components are positioned on a PCB and reflow soldered. For this end, a PCB with mounted electronic components is automatically conveyed to a vision inspection apparatus, and an X-ray or image capturing device is used to inspect the positioning of the electronic components, their soldered states, etc.

Thus, when the above shield apparatus 1 has been applied, because the electronic components stored within the shield apparatus 1 are covered by the shield apparatus 1, it may be difficult to perform suitable vision inspection.

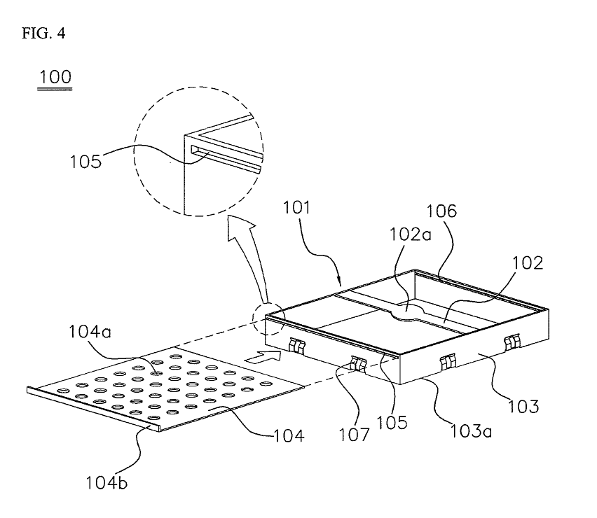

For this end, a configuration such as that in FIG. 4 may be suggested. FIG. 4 is a view illustrating a shield apparatus 100 according to another embodiment. Here, because the coupling structure of a metal clip 107 is the same as that in FIG. 1, a description thereof will not be provided.

According to this embodiment, a case 101 of a shield apparatus 100 is open from top to bottom and is covered with a metal cover 104 at the top opening.

Slots 105 and 106 are defined opposite to one another in the front and rear sidewalls 103 of the case 101 near the tops and along the entire widths thereof, and the metal cover 104 is inserted through the slots 105 and 106 (shown with the arrow in FIG. 4) to cover the open top of the case 101.

As another example that is not illustrated, a slot 105 may be defined only in the front sidewall, and instead of a slot defined in the rear sidewall, an emboss line may be formed to project and support the metal cover 104.

A pickup land 102a may be formed across the top opening. That is, as shown in FIG. 4, by forming a bridge 102 extending from respectively opposite edges of the open top, and forming a pickup land 102a at the center of the bridge 102, the pickup land 102a may be used in vacuum pickup of the case 101.

With this configuration, the case 101 may be subject to a vacuum pickup and reflow soldered on a ground pattern of a PCB, without the metal cover 104 covering it, and then vision inspection may be performed through the open top, after which the metal cover 104 may be inserted and fixed in the slots 105 and 106 defined in the sidewalls 103 of the case 101 to cover the open top. Accordingly, a shield apparatus according to embodiments may be applied having the same effects as the embodiments described above, while not altering a related art manufacturing line.

Heat dissipating holes 104a may be defined in the metal cover 104 to dissipate heat.

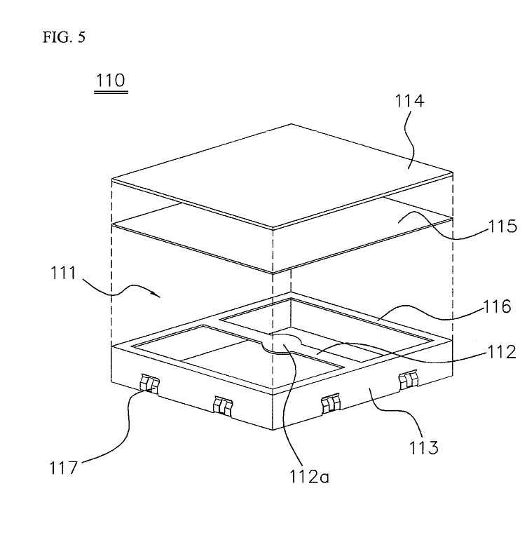

FIG. 5 is a view illustrating a shield apparatus 110 according to another embodiment.

According to this embodiment, a flange 116 is integrally formed extending inward along the edge of the open top of the case 111, and an electrically conductive adhesive tape 115 may be interposed to attach a metal cover 114 to the flange 116.

Here also, a pickup land 112a may be formed across the open top, as in the embodiment illustrated in FIG. 5.

Here, the electrically conductive adhesive tape 115 may adhered to only the portion on the reverse surface of the metal cover 114 corresponding to the flange 116 and pickup land 112a and a bridge 112, instead of the entire reverse surface.

Selectively, the flange 116 may be formed extending outward instead of inward from the edge at the open top.

According to this configuration, the case 111 may be reflow soldered on a ground pattern of a PCB, without the metal cover 114 covering it, and then vision inspection may be performed through the open top, after which the metal cover 114 may be adhered and fixed to the flange 116 in order to cover the open top of the case 111. Accordingly, a shield apparatus according to embodiments may be applied having the same effects as the embodiments described above, while not altering a related art manufacturing line.

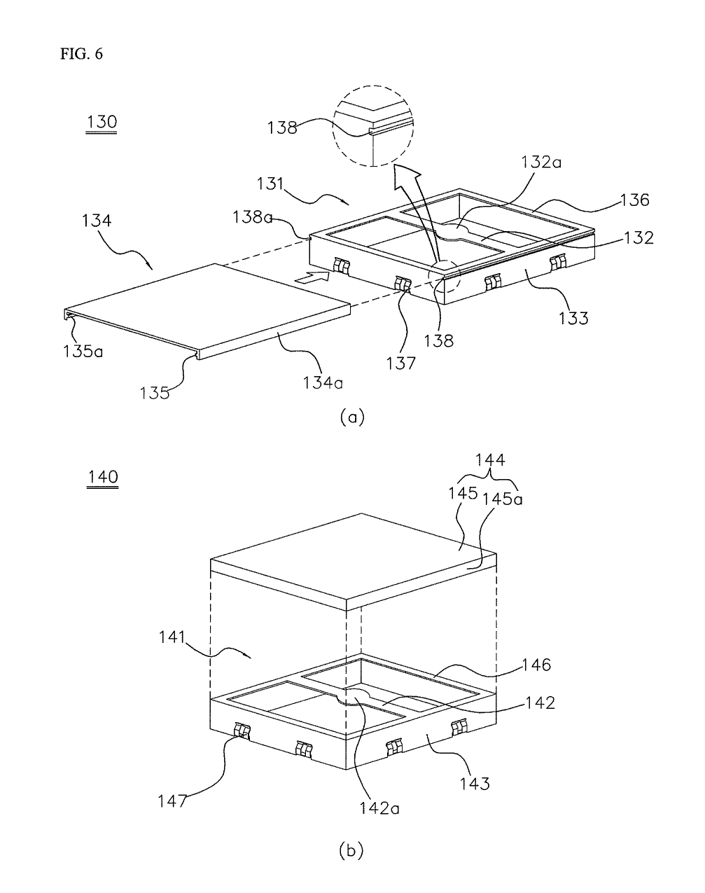

FIG. 6 is a view illustrating shield apparatuses 130 and 140 according to other embodiments.

Referring to FIG. 6(a), a case 131 of a shield apparatus 130 is open at the top and bottom and covered at the top opening by a metal cover 134. As in the embodiments above, by forming a bridge 132 extending from respectively opposite edges at the open top, and a pickup land 132a at the center of the bridge 132, the case 131 may be subject to vacuum pickup using the pickup land 132a.

Recesses 138 and 138a are defined in portions near the top ends of opposite sidewalls 133, respectively, of the case 131, to extend along the sidewalls 133. While the sectional shape of the recesses 138 and 138a in this embodiment is rectangular, it is not limited thereto.

Also, the metal cover 134 is configured with a base, and sidewalls 134a extending perpendicularly from the edges of the base that correspond to both the sidewalls 133 of the case 131, and ribs 135 and 135a are formed projecting inward on the inner sides of the sidewalls 134a to correspond to the recesses 138 and 138a defined in the sidewalls 133 of the case 131.

According to this configuration, the metal cover 134 is inserted at the sides of the case 131, whereby coupling is achieved through the ribs 135 and 135a of the metal cover 134 being fitted and slid along the recesses 138 and 138a defined in the sidewalls 133 of the case 131.

Also, as illustrated in FIG. 6(b), a case 141 of a shield apparatus 140 is open at the top and bottom and is covered at the top opening by a metal cover 144. As in the embodiments described above, by forming a bridge 142 extending from respectively opposite edges at the top opening, and a pickup land 142a at the center of the bridge 142, the case 141 may be subject to vacuum pickup using the pickup land 142a.

The metal cover 144 is configured with a base 145, and a sidewall 145a formed integrally with the base 145 to extend perpendicularly from the edges thereof, whereby the metal cover 144 may be mechanically inserted over the case 141 to cover the top opening.

In the embodiments of FIG. 6, while flanges 136 and 146 are shown formed on the cases 131 and 141 as examples, the flanges 136 and 146 may not be formed.

Instead of the shield apparatuses 100 and 110 in FIGS. 4 and 5, the shield apparatus 1 in FIG. 1 may be applied corresponding to a related art vision inspection. That is, by making the diameter of heat dissipating holes formed in the top surface 12 of the case 10 large, vision inspection may be performed through the holes, after which a portion of the heat dissipating holes may be covered with tape to yield a sufficient level of EMI shielding effectiveness, while making no changes to a related art manufacturing line.

According to the above configurations, because a shield apparatus for EMI shielding according to embodiments, with solderable metal clips inserted over it so that they do not project from the sidewall ends of the case, is surface mounted on the surface of a PCB ground pattern by means of a vacuum pickup, and then the metal clips are reflow soldered, automation is facilitated, manufactured yield is improved, and manufacturing costs are reduced.

Because a case made of a material that is thin, has good mechanical strength, is inexpensive, and is not solderable can be applied, manufacturing cost is low, and automation is facilitated.

Improved EMI shielding effectiveness and good soldering strength are obtained by making reliable electrical contact for the metal clips and sidewall ends of the case that are maintained horizontally on a ground pattern.

A case and metal clip can be coupled resiliently in a mechanically reliable manner, and re-working is made easy.

The shield apparatus can also be applied to PCB ground patterns of various configurations—particularly, to ground patterns that are narrow.

Standardization of the metal clip and case is facilitated, allowing for mass-production and reduction of manufacturing costs.

While the case is thin, because the metal clips inserted on the case are soldered, soldering strength is improved in proportion to the soldered portions, or the widths of the bottom surfaces of the metal clips, and wobbling during reflow soldering is reduced as well.

Because thermal conductivity and electric wave absorbency can be improved, it is easy to provide a shield apparatus capable of EMI isolation. Here, mechanical strength is enhanced by the EMI isolating wall.

Further, because metal clips, recesses, and the thickness of the case have common dimensional and structural specifications, the case and metal clips have reliable insertion and removal force.

While a detailed description of embodiments of the present invention has been provided above, it will be understood by those having skill in the art that various changes, substitutions and alterations can be made hereto without departing from the spirit and scope of the invention as defined by the appended claims.

What is claimed is:

1. A shield apparatus for EMI (ElectroMagnetic Interference) shielding, comprising:
a case of metal that is electrically conductive and box-shaped with at least one open side, and having a recess defined from an end of a sidewall thereof defining the open side; and
a metal clip having a bottom surface than a thickness of the sidewall of the case, the metal clip housed in the recess, resiliently inserted on the sidewall, and electrically connected to the case, wherein
at least the bottom surface of the metal clip does not project from within the recess, and
the shield apparatus is picked-up with a vacuum pickup and supplied on a ground pattern of a PCB (Printed Circuit Board) and soldered at the bottom surface of the metal clip.

2. The shield apparatus of claim 1, wherein the case is manufactured by pressing a high-strength metal sheet that is difficult to reflow solder with solder cream.

3. The shield apparatus of claim 1, wherein the metal clip is formed with one of tin and silver plated on a high-strength metal sheet that is difficult to reflow solder with solder cream.

4. The shield apparatus of claim 1, wherein
the sidewall defines a notch respectively in an outer surface and an inner surface thereof at regions proximate to a bottom surface of the recess, or the sidewall defines a through-hole therethrough, and
resiliently opposed portions of the metal clip are seated in each of the notches, respectively, or in the through-hole.

5. The shield apparatus of claim 1, wherein the case defines a plurality of heat dissipating holes in a top surface thereof.

6. The shield apparatus of claim 1, further comprising one selected from an EMI absorbing rubber sheet, a heat conductive rubber sheet, and an EMI shielding electrically conductive rubber isolating wall, formed on an opposite surface of a top surface of the case.

7. The shield apparatus of claim 1, wherein the metal clip is formed as a single piece including at least one pair of supporting portions extending vertically from either end widthwise of the bottom surface of the metal clip, and a pair of resilient contacting portions bent to extend at a predetermined angle inward from each of the supporting portions, respectively.

8. The shield apparatus of claim 7, wherein the bottom surface of the metal clip defines a plurality of holes, and solder balls are mounted on a portion of the plurality of holes.

9. The shield apparatus of claim 1, wherein the metal clip has the same dimensions and material when provided in plurality, and the dimensions of the recesses are the same.

10. The shield apparatus of claim 1, wherein a side opposite the open side is additionally open, and further comprising an electrically conductive cover covering the additionally open side.

11. The shield apparatus of claim 10, wherein the electrically conductive cover has a sheet configuration and covers the additionally open side by being inserted in a slot defined in the sidewall of the case.

12. The shield apparatus of claim 10, wherein the electrically conductive cover is formed of a base and sidewalls integrally extending perpendicularly from edges of the base, and covers the additionally open side by being mechanically inserted over a top surface of the case.

13. The shield apparatus of claim 10, wherein the electrically conductive cover has a sheet configuration and covers the additionally open side, with an electrically conductive adhesive tape interposed therebetween.

14. The shield apparatus of claim 10, wherein the electrically conductive cover includes a base, and sidewalls integrally extending perpendicularly from any one pair of opposed edges of the base, and the electrically conductive cover covers the additionally open side by being slid from side surfaces of the case and coupled to the case.

15. The shield apparatus of claim 14, wherein the electrically conductive cover includes a rib respectively projecting along inner sides of the sidewalls thereof, the case defines a slot respectively along the sidewalls thereof, and the rib formed respectively on the sidewalls of the electrically conductive cover is fitted in the slot defined respectively in the sidewalls of the case to slide therealong, to couple the electrically conductive cover to the case.

16. The shield apparatus of claim 10, wherein opposed edges of the additionally open side are connected to each other by connecting portions respectively having a land formed at a center thereof for a vacuum pickup.

17. The shield apparatus of claim 1, wherein the shield apparatus is reel-packaged on carrier tape or is packaged on a tray for surface mounting.

18. The shield apparatus of claim 1, wherein at least a portion of the top surface of the case is a flat surface for the pickup.

19. The shield apparatus of claim 1, wherein the shield apparatus is capable of being surface mounted with the vacuum pickup and reflow soldered with solder cream.

20. The shield apparatus of claim 1, wherein an insertion force and a removal force of the metal clip with respect to the case is 100 gf or greater.

21. The shield apparatus of claim 1, wherein after the shield apparatus is soldered to the ground pattern of the PCB, the case is separated from the metal clip by means of a predetermined removal force.

22. The shield apparatus of claim 1, wherein the bottom surface of the metal clip retains a horizontal disposition.

23. A PCB (Printed Circuit Board) on which the shield apparatus of claim 1 is surface mounted and soldered.
